(19) United States
(12) Patent Application Publication
(10) Pub. No.: US 2023/0366090 A1
(43) Pub. Date: Nov. 16, 2023

(54) METHOD FOR CONTROLLING SUBSTRATE CARRIER OF DEPOSITION APPARATUS

(71) Applicant: SKY TECH INC., Hsinchu County (TW)

(72) Inventor: JING-CHENG LIN, Hsinchu County (TW)

(21) Appl. No.: 17/742,165

(22) Filed: May 11, 2022

(51) Int. Cl. C23C 16/458

(52) U.S. Cl. CPC C23C 16/4586; C23C 16/4585

(57) ABSTRACT

A method for a deposition apparatus is disclosed. The deposition apparatus includes a chamber, a substrate carrier, a blocker and a cover ring. The cover ring is disposed on the blocker. The substrate carrier carries a wafer and moves with respect to the blocker. A position where the substrate carrier contacts the cover ring start is defined as a contact position, and a first position below the contact position and a second position above the contact position are also defined. When the reaching the first position, a movement speed of the substrate carrier is decreased, and the substrate carrier carries the cover ring to move away from the blocker. When reaching the second position, the movement speed of the substrate carrier away from the blocker is increased. Collision between the wafer and the deposition apparatus is eliminated to prevent undesired particles from occurring and the wafer from being damaged.

### TECHNICAL FIELD

This disclosure relates to a method for controlling a substrate carrier of a deposition apparatus. The method eliminates collision between wafer and parts of deposition apparatus, so as to reduce undesired particles produced by the collision, also to prevent the wafer from being damaged.

### BACKGROUND

A deposition apparatus, such as a chemical vapor deposition (CVD) apparatus, a physical vapor deposition (PVD) apparatus or an atomic-layer deposition (ALD) apparatus, is commonly employed in manufacturing of integrated circuits, light-emitting diodes and displays, etc.

Generally, a deposition apparatus includes a chamber and a substrate carrier. The substrate carrier is positioned within the chamber configured to carry at least one wafer. To exemplify the PVD, it is required to dispose a target material within the chamber and to have the target material facing the wafer on the substrate carrier. When performing the PVD, the substrate carrier moves the wafer thereon to approach the target material, thereafter a noble gas and/or reactive gas is transferred into the chamber. Meanwhile bias electricity is applied on the target material and the substrate carrier, and the substrate carrier also heats up the wafer carried thereon. The noble gas within the chamber is ionized by an effect of high-voltage electric field. The ionized noble gas is attracted by the bias electricity applied on the target material to bombard the target material. Atoms or molecules splashed, flying out from the target material are attracted by the bias electricity on the substrate carrier, and deposited on a surface of the heated-up wafer to form a thin film on the surface of the wafer.

Another type of deposition process, the atomic-layer deposition (ALD) is to coat a wafer with materials at single-atom level, and to coat it layer by layer. To be more specific, two types of chemical substance commonly so called “precursors”, which are mainly employed to be sent into the chamber sequentially and to react with the wafer for coating.

Nevertheless, for all types of the deposition apparatus, as the movable substrate carrier contacts other components, undesired particles may be formed to contaminate the wafer within the chamber, and hence to result in a poor production yield.

### SUMMARY

To overcome the abovementioned drawback, this disclosure provides a method for controlling a substrate carrier of a deposition apparatus. The method effectively reduces the contamination by undesired particles generated during the movement of the substrate carrier, and to prevent the substrate carrier from causing collision or friction with other components, in order to improve the production yield.

Accordingly, one object of this disclosure is to provide a method for controlling a substrate carrier of a deposition apparatus. The deposition apparatus includes a chamber, a substrate carrier, a blocker and a cover ring. The substrate carrier, the blocker and the cover ring are disposed within a containing space of the chamber. The blocker is configured to carry a cover ring, while the substrate carrier is configured to carry at least one wafer and to move with respect to the blocker and the cover ring.

According to the method, a movement speed of the substrate carrier is decreased when the substrate carrier is located below the blocker and a distance between the substrate carrier and the blocker is less than a threshold value. Furthermore, the movement speed of the substrate carrier is decreased to a minimum value when the substrate carrier and/or the wafer thereon contact the cover ring. Thereby, the collision between the wafer and the deposition apparatus is eliminated to prevent undesired particles from occurring and the wafer from being damaged.

When contacting the cover ring, the substrate carrier carries the cover ring to move from the blocker to an upper side above blocker. When the distance between of the substrate carrier and the blocker exceeds the threshold value, the movement speed of the substrate carrier moving away from the blocker is increased.

One object of this disclosure is to provide the aforementioned method, wherein when the substrate carrier carries the wafer and the cover ring back toward the blocker from the upper side, and allows the cover ring to contact the blocker, a contact position at where the cover ring contacts the blocker is defined.

When the substrate carrier with the wafer and the cover ring thereon are located above the blocker and the distance between the substrate carrier and the blocker is less than the threshold value, the movement speed of the substrate carrier is decreased. When the cover ring contacts the blocker, the movement speed is decreased into a minimum value. Thereby, it is able to eliminate collision when the cover ring contacts the blocker, to prevent the undesired particles from occurring.

After the cover ring contacts the blocker, the substrate carrier moves to the lower side below the blocker, and so as to place the cover ring on the blocker. When a distance between the substrate carrier and the contact position exceeds the threshold value, the movement speed of the substrate carrier moving away from the blocker is increased.

To achieve the aforementioned objects, this disclosure provides a method for controlling a substrate carrier of a deposition apparatus. The deposition apparatus includes a chamber, a substrate carrier, a blocker and a cover ring. The substrate carrier, the blocker and the cover ring are disposed within a containing space of the chamber, and the blocker is configured to carry the cover ring. The method includes the following steps as: utilizing the substrate carrier to carry a wafer, and moving the substrate carrier toward the blocker and the cover ring from a lower side below the blocker, and defining a contact position at where the substrate carrier contacts the cover ring; defining a first position above the contact position and a second position below the contact position; decreasing a movement speed of the substrate carrier moving toward the blocker and the cover ring when the substrate carrier reaches the first position; moving the substrate carrier to contact the cover ring on the blocker; moving the substrate carrier to bring the cover ring to move away from the blocker; and increasing the movement speed of the substrate carrier moving away from the blocker when the substrate carrier reaches the second position.

This disclosure provides another method for controlling a substrate carrier of a deposition apparatus. The method includes the following steps as: driving the substrate carrier to carry a wafer and the cover ring, and moving the substrate carrier toward the blocker from an upper side of the blocker, and defining a contact position at where the cover ring contacts the blocker; defining a first position below the contact position and a second position above the contact position; decreasing a movement speed of the substrate carrier moving toward the blocker when the substrate carrier reaches the second position, then; allowing the cover ring to contact the blocker at the contact position; moving the substrate carrier to the first position and to place the cover ring on the blocker; and increasing the movement speed of the substrate carrier moving away from the blocker when the substrate carrier reaches the first position.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a cross-sectional view illustrating a deposition apparatus according to one embodiment of this disclosure.

FIG. 2 is a flowchart describing a method for controlling a substrate carrier of the deposition apparatus, according to one embodiment of this disclosure.

FIG. 3 is a cross-sectional view illustrating a substrate carrier of the deposition apparatus reaches a first position, according to one embodiment of this disclosure.

FIG. 4 is a cross-sectional view illustrating the substrate carrier contacting a cover ring at a contact position, according to one embodiment of this disclosure.

FIG. 5 is a cross-sectional view illustrating the substrate carrier which is at a second position, according to one embodiment of this disclosure.

FIG. 6 is a flowchart describing the method for controlling a substrate carrier of a deposition apparatus, according to another embodiment of this disclosure.

FIG. 7 is a cross-sectional view illustrating the substrate carrier located above the second position, according to another embodiment of this disclosure.

### DETAILED DESCRIPTION OF THE PREFERRED EMBODIMENTS

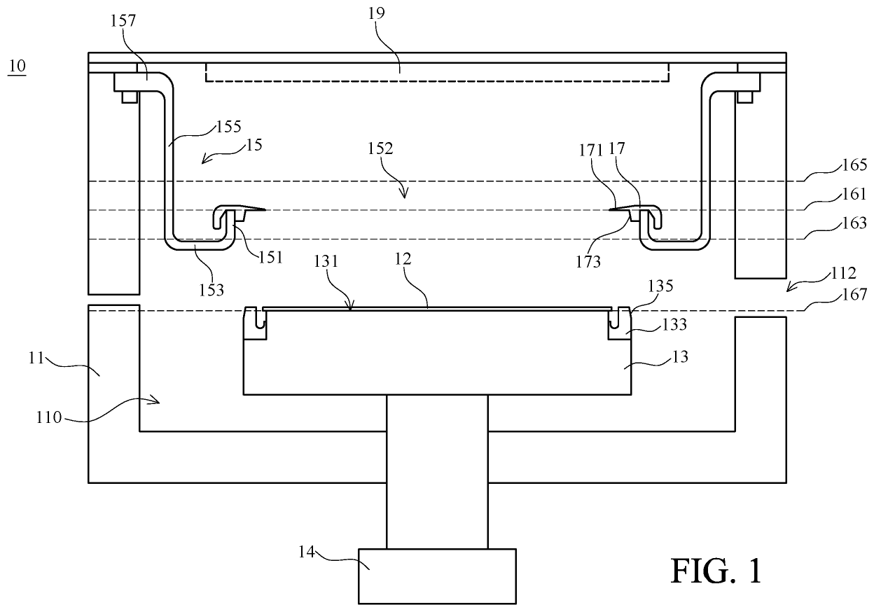

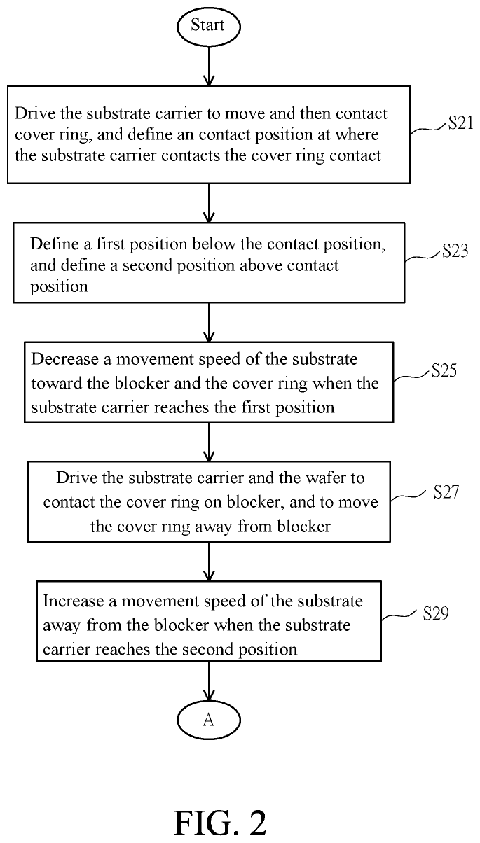

Referring to FIG. 1 and FIG. 2, wherein FIG. 1 is a cross-sectional view illustrating a deposition apparatus for exemplifying a method for controlling substrate carrier of deposition apparatus; and FIG. 2 is a flowchart describing the method for controlling substrate carrier of deposition apparatus, according to one embodiment of this disclosure. The deposition apparatus 10 includes a chamber 11, a substrate carrier 13, a blocker 15 and a cover ring 17. The chamber 11 has a containing space 110, for containing the substrate carrier 13, the blocker 15 and the cover ring 17.

The blocker 15 includes an end connected to the chamber 11 and another end formed with a hollow opening 152 within the containing space 110. In more detail, the blocker 15 includes a ring-shaped wall 151, a ring-shaped bottom153, a ring-shaped barrier 155 and a ring-shaped connecting segment 157. The ring-shaped wall 151 is connected to the ring-shaped barrier 155 via the ring-shaped bottom153. The ring-shaped barrier 155 is connected to the chamber 11 via the ring-shaped connecting segment 157.

In at least one embodiment, the ring-shaped wall 151 is tubular and equipped with a hollow opening 152. The ring-shaped wall 151 has a circumstance and a height smaller than those of the ring-shaped barrier 155. In at least one embodiment, the ring-shaped wall 151 and the ring-shaped barrier 155 are disposed in a concentric manner, with the ring-shaped wall 151 disposed within the ring-shaped bottom153. The ring-shaped wall 151 also has a lower end connected to a lower end of the ring-shaped barrier 155 via the ring-shaped bottom153, as a protrusion protruding upward from the ring-shaped bottom153 to form the hollow opening 152.

The ring-shaped connecting segment 157 has a radially-inner side connected to an upper end of the ring-shaped barrier 155, and has a radially-outer side connected to the chamber 11, thereby the entire blocker 15 is fastened on an interior of the chamber 11. In the other hand, the cover ring 17 is a ring-shaped member and is formed with a diameter larger than that of the hollow opening 152, such that the cover ring 17 is able to be placed to hang on the ring-shaped wall 151 of the blocker 15.

The substrate carrier 13 is disposed within a vertical projection of the hollow opening 152 on the blocker 15 (such as up-down direction of FIG. 1). Moreover, the substrate carrier 13 has a carrying surface 131, and the substrate carrier 13 carries a wafer 12 on the carrying surface 131, so as to move the wafer 12 with respect to the blocker 15. In one embodiment of this disclosure, the substrate carrier 13 is connected to an elevating unit 14. The elevating unit 14 is configured to drive the substrate carrier 13 to move with respect to the blocker 15. In one embodiment, the elevating unit 14 is a linear actuator.

The chamber 11 is disposed with a wafer gate 112, a wafer-passing position 167 is defined on an extending direction of the wafer gate 112 (such as left-right direction of FIG. 1) and below the first positon 163. In one embodiment, a robotic arm (not shown in FIGs) is employed to transport the wafer 12 into the containing space 1120, and place the wafer 12 onto the substrate carrier 13 at the wafer-passing position 167. In an opposite manner, the robotic arm is employed to pick up the wafer 12 from the substrate carrier 13 at the wafer-passing position 167, and then move the wafer 12 out of the chamber 11.

In one embodiment, the elevating unit 14 drives and moves the substrate carrier 13 disposed below a lower side of the blocker 15 and the cover ring 17, and moves the substrate carrier 13 toward the blocker 15 and the cover ring 17. For example, the substrate carrier 13 is initially disposed at the wafer-passing position 167, and when the wafer 12 is placed thereon the substrate carrier 13 moves the wafer 12 toward the blocker 15 and the cover ring 17. A movement speed of the substrate carrier 13 moving between the wafer-passing position 167 and a first position 163, is larger than the movement speed of the substrate carrier 13 moving between the first position 163 and a contact position 161. Driven by the elevating unit 14, the substrate carrier 13 passes through and enters the hollow opening 152 of the blocker 15, and then moves to an upper side above the blocker 15.

As shown in FIG. 2, the method according this disclosure includes numerous steps, as S21, S23, S25, S27, and S29. In S21, the method is to drive the substrate carrier 13 with the wafer 12 thereon to move then contact the cover ring 17 hung on the blocker 15, when the substrate carrier 13 passes through the hollow opening 152. Also, in S21, the method is further to define the aforementioned contact position 161 at where the substrate carrier 13 and/or the wafer 12 thereon contact the cover ring 17. Alternatively, the contact position 161 may be where the cover ring 17 is placed and hung on the blocker 15.

As shown in FIG. 1 and FIG. 2, S23 is to define the aforementioned first position 163 below the contact position 161, and to define a second position 165 above the contact position 161.

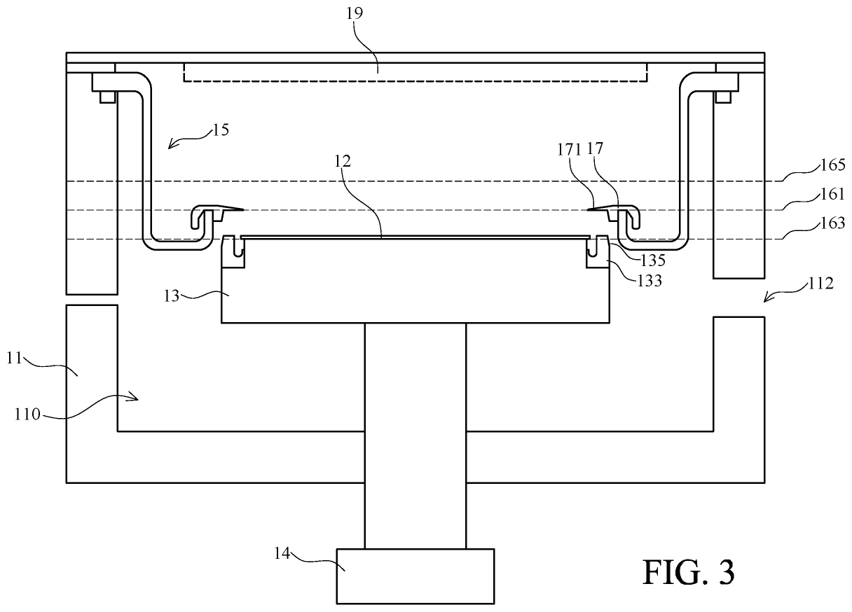

As shown in FIG. 2 and FIG. 3, in S25 when the substrate carrier 13 approaches the blocker 15 and the cover ring 17 from a lower side below the blocker 15 and then reaches the first position 165, the method is to decrease a movement speed of the substrate carrier 13 moving toward the blocker 15 and the cover ring 17. Thereafter, the substrate carrier 13 keeps approaching the blocker 15 and the cover ring 17 in a relatively slow movement speed.

To be specific, a distance between the first position 163 and the contact position 161 may be less than 1 centimeter (cm); while a distance between the second position 165 and the contact position 161 may also be less than 1 cm. Accordingly, the greater those distances therebetween are, the easier to control the movement speed of the substrate carrier 13 driven by the elevating unit 14, thereby to have more response time for preventing the substrate carrier 13 (and/or the wafer 12 thereon) from causing friction or collision with the cover ring 17. However, the greater those distances therebetween are, the longer for the substrate carrier 13 to reach the predefined positions (such as the contact position 161 and the second position 165), this may cause inefficiency to production process.

The inventor of this disclosure has performed several experiments, to consider that the distance between the first position 163 and the contact position 161 is preferable to be in a range between 2 millimeters (mm) and 5 mm. In the other hand, the distance between the second position 165 and the contact position 161 is also preferable to be in a range between 2 mm and 5 mm. Thereby, it is able to reduce the friction or collision between the substrate carrier 13 and the wafer 12 and the cover ring 17, and at same time to maintain an acceptable efficiency of the production process.

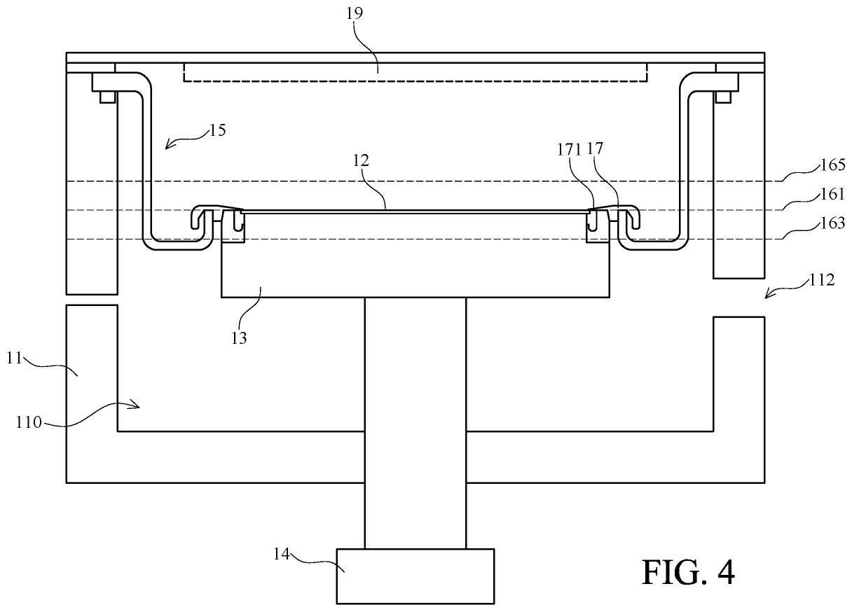

Next, as shown in FIG. 2 and FIG. 4, in S27 the substrate carrier 13 and the wafer 12 contact cover ring 17 at the contact position 161, and then the elevating unit 14 keeps to move the substrate carrier 13 and the wafer 12 to move upward, such that the substrate carrier 13 drives the cover ring 17 to move away from the blocker 15. At this moment, the substrate carrier 13 carries the cover ring 17, and a pressing portion 171 provided on a radially-inner portion of the cover ring 17 contacts an edge of the wafer 12, so as to fix the wafer 12 on the substrate 13.

Specifically, when the substrate carrier 13 with the wafer 12 thereon reaches the first position 163, the movement speed of the substrate carrier 13 is decreased, and then the movement speed is decreased to a minimum value when reaching the contact position 161. Thereby, the friction or collision between the substrate carrier 13 and the wafer 12 thereon and also the cover ring 17, can be effectively reduced, in order to prevent the cover ring 17 from damaging the wafer 12.

In practical use, the substrate carrier 13 includes an alignment ring 133. The alignment ring 133 is disposed to surround the carrying surface 131, and is configured to carry the wafer 12. The alignment ring 133 is formed with a first aligning portion 135, while the cover ring 17 is formed with a second aligning portion 173 corresponding to the first aligning portion 135. In an example, the first aligning portion 135 is an annular bevel at a radially-outer edge of the alignment ring 133, while the second aligning portion 175 is an annular bevel at a radially-inner edge of the cover ring 17, for example. Also, the first aligning portion 135 and the second aligning portion 175 are formed with proximately identical bevel angles, for fitting and aligning with each other.

When the substrate carrier 13 moves to contact the cover ring 17, the alignment ring 133 thereon has the beveled first aligning portion 135 contacting and guiding the second aligning portion 175 of the cover ring 17 into a fixed position, so as to align the cover ring 17 with the substrate carrier 13, and in order to fasten the wafer 12. However, it should be noted that when the cover ring 17 and substrate carrier 13 contact to align with each other by the first aligning position 135 and the second aligning position 173, friction can occur therebetween and thereby to produce undesired particles, and so as to cause contamination.

Accordingly, the faster the substrate carrier 13 comes to contact the cover ring 17, the more friction and undesired particles may come out therebetween, and hence to worsen the contamination to components disposed within the containing space 110 of the chamber 11 (such as the wafer 12, the substrate carrier 13 and/or the blocker 15).

Moreover, during the alignment of the cover ring 17 and the substrate carrier 13, the cover ring 17 may have a lateral displacement parallel to the carrying surface 131, for example. Such lateral displacement of the cover ring 17 may turn to grind, and hence damage surface of the wafer 12, when the cover ring 17 contacts the wafer 12.

To improve the abovementioned drawbacks of contaminating particles and the damage to the wafer 12, the method according to this disclosure is provided to decrease the movement speed of the substrate carrier 13 toward the blocker 15 and the cover ring 17, and further to decrease the movement speed to the minimum value soon as the substrate carrier 13 reaches the first position 163. Thereby, the undesired contaminating particles can be greatly reduced, and furthermore, the grinding damage to the surface of the wafer 12 can be effectively prevented as well.

However, the alignment ring 133 is not a necessary component to the substrate carrier 13. In practical use, the substrate carrier 13 may be configured to have the beveled first aligning position 135 formed integrally around the carrying surface 131, and hence no need of the alignment ring 133.

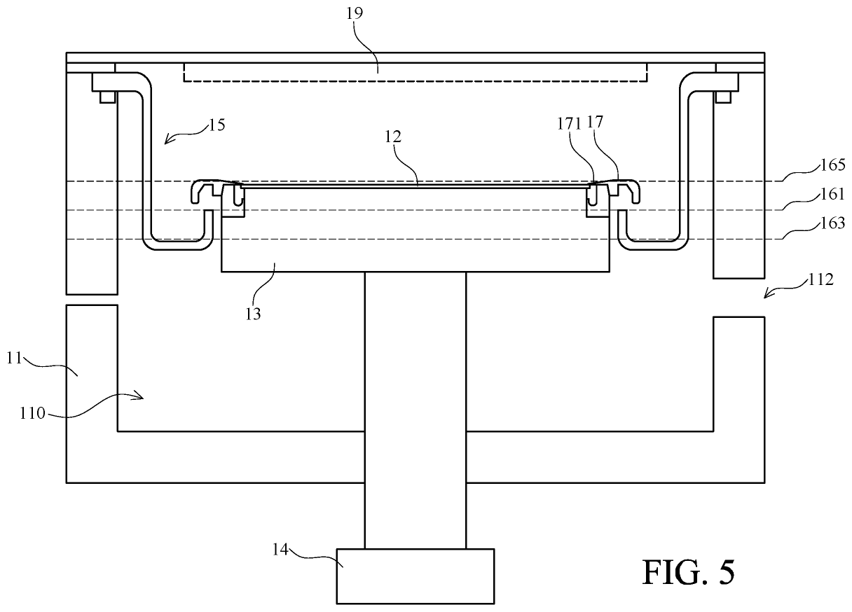

Then next, as shown in FIG. 2 and FIG. 5, S29 is to control the elevating unit 14 continuously driving the substrate carrier 13 to move upward, thereby to lift up and carry the cover ring 17 away from the blocker 15 by the substrate carrier 13. Here, at this moment, the cover ring 17 is probably not aligned with the blocker 15, therefore to control the elevating unit 14 driving the substrate carrier 13 to move upward and away from the blocker15 in a decreased, relatively slow movement speed, between the contact position 161 and the second position 165. And when the substrate carrier 13 reaches the second position 165 above the blocker 15, the elevating unit 14 drives the substrate carrier 13 to move away from the blocker 15 in an increased, and relatively fast movement speed.

As shown in FIG. 5, the deposition apparatus 10 is exemplified as a physical-vapor deposition (PVD) apparatus, which includes a target material 19 disposed within the containing space 110 and on a ceiling of the chamber 11, and located above the blocker 15 and the cover ring 17. As the elevating unit 14 drives the substrate carrier 13 to carry the wafer 12 and the cover ring 17 away from the blocker 15, and toward the target material 19, thereby to adjust a distance between the wafer 12 on the substrate carrier 13 and the target material 19, in order to configure parameters for the production process of deposition.

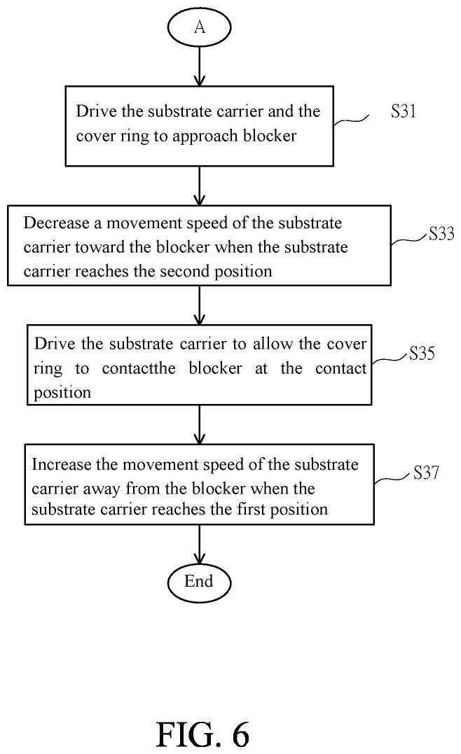

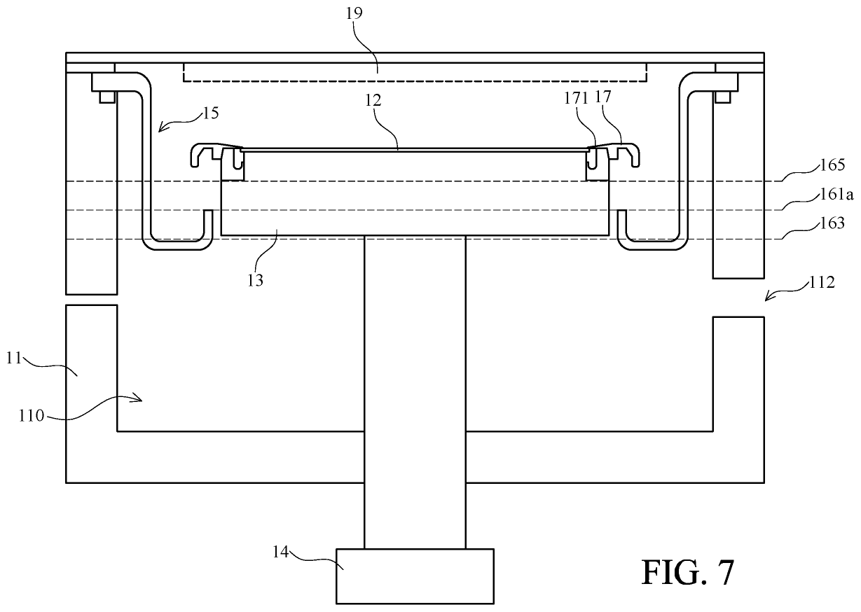

Referring to FIG. 6, which is a flowchart describing the method for controlling substrate carrier of deposition apparatus, according to another embodiment of this disclosure. The method in this embodiment is adapted to the deposition apparatus 10 in a state after the substrate carrier 13 carries the wafer 12 and the cover ring 17 to a position between the second position 165 and the target material 19 and complete the deposition process, as shown in FIG. 7. The method in this embodiment also includes numerous steps, as the S31, the S33, the S35 and the S37. S31 is to control to the elevating unit 14 driving the substrate carrier 13 with the wafer 12 and the cover ring 17 to move toward the blocker 15 from an upper side of the blocker 15, in a manner such as from the target material 19 to the blocker 15. As a process of returning to initial position, the S31 may be performed after the aforementioned S29 as shown in FIG. 2.

In this embodiment, the contact position 161a is defined at where the cover ring 17 starts to contact the blocker 15, and similar to the aforementioned embodiment, the first position 163 is defined below the contact position 161, while the second position 165 is defined above the contact position 161.

Then as shown in FIG. 5, In S33 the elevating unit 14 drives the substrate carrier 13 to reach the second position 165 above the blocker 15, then to decrease the movement speed of the substrate carrier 13 toward the blocker 15.

Next, as shown in FIG. 4, In S35, the substrate carrier 13 continuously moves the wafer 12 and the cover ring 17 to move toward the blocker 15, allow the cover ring 17 to contact the blocker 15 at the contact position 161a (FIG. 7). Thereafter, to continue driving the substrate carrier 13 with the wafer 12 to move toward the first position 163, to move away from the blocker 15 and hence to allow the cover ring 17 to be hung on the blocker 15. Also to mention, the movement speed of the substrate carrier 13 with the wafer 12 and the cover ring 17 thereon is decreased to a minimum value, at the contact position 161a.

Next, as shown in FIG. 3, in S37, the elevating unit 14 drives the substrate carrier 13 to continuously to move away from the blocker 15, until reaching the first position 163 below the blocker 15, then to increase the movement speed of the substrate carrier 13 moving away from the blocker 15.

At last, as shown in FIG. 1, the elevating unit 14 drives the substrate carrier 13 to continuously to move to the wafer-passing position 167, and then an robotic arm is to utilized to extract the processed wafer 12 from the substrate carrier 13.

The above disclosure is only the preferred embodiment of this disclosure, and not used for limiting the scope of this disclosure. All equivalent variations and modifications on the basis of shapes, structures, features and spirits described in claims of this disclosure should be included in the claims of this disclosure.

We claim:

1. A method for controlling a substrate carrier of a deposition apparatus, wherein the deposition apparatus comprises a chamber, a substrate carrier, a blocker and a cover ring, the substrate carrier, the blocker and the cover ring are disposed within a containing space of the chamber, and the blocker is configured to carry the cover ring; the method comprising:
utilizing the substrate carrier to carry a wafer to move from a lower side below the blocker and toward the blocker and the cover ring, and defining a contact position at where the substrate carrier contacts the cover ring;
defining a first position below the contact position, and defining a second position above the contact position;
decreasing a movement speed of the substrate carrier moving toward the substrate carrier and the cover ring, after the substrate carrier reaches the first position;
moving the substrate carrier to contact the cover ring on the blocker at the contact position;
driving the substrate carrier to carry the cover ring to move away from the blocker; and
increasing the movement speed of the substrate carrier moving away from the blocker, after the substrate carrier reaches the second position.

2. The method according to claim 1, wherein a distance between the first position and the contact position is less than 1 centimeter.

3. The method according to claim 2, wherein the distance between the first position and the contact position is in a range between 2 millimeter and 5 millimeter.

4. The method according to claim 1, wherein a distance between the second position and the contact position is less than 1 centimeter.

5. The method according to claim 4, wherein the distance between the second position and the contact position is in a range between 2 millimeter and 5 millimeter.

6. The method according to claim 1, further comprising:
defining a wafer-passing position below the blocker and the cover ring, and having the substrate carrier positioned at the wafer-passing position; and
driving the substrate carrier to carry the wafer moving toward the blocker and the cover ring from the wafer-passing position; wherein the movement speed of the substrate carrier between the wafer-passing position and the first position is faster than the movement speed of the substrate carrier between the first position and the contact position.

7. The method according to claim 6, further comprising utilizing a robotic arm to transport the wafer onto the substrate carrier at the wafer-passing position, before driving the substrate carrier to move toward the blocker and the cover ring.

8. The method according to claim 1, further comprising:
disposing a target material on a ceiling of the chamber; and
driving the substrate carrier to carry the wafer and the cover ring to move away from the blocker and toward the target material.

9. The method according to claim 1, wherein the substrate carrier includes an alignment ring and a carrying surface; wherein
the carrying surface is configured to carry the wafer;
the alignment ring is disposed to surround the carrying surface;
the alignment ring includes a first aligning portion; and
the cover ring includes a second aligning portion;
when substrate carrier moves toward the cover ring, the second aligning portion of the cover ring contacts the first aligning portion of the alignment ring, and the cover ring is guided to a fixed position on the substrate carrier.

10. The method according to claim 9, wherein the contact position is defined at where the second aligning portion of the cover ring and the first aligning portion of the alignment ring start to contact each other.

11. The method according to claim 1, wherein
the substrate carrier includes a carrying surface and a first aligning portion;
the carrying surface is configured to carry the wafer, and the first aligning portion surrounds the carrying surface;
the cover ring includes a second aligning portion;
when the substrate carrier moves toward the cover ring, the second aligning portion of the cover ring contacts the first aligning portion of the substrate carrier, and the cover ring is guided to a fixed position related to the substrate carrier; and
wherein the contact position is defined at where the second aligning portion of the cover ring and the first aligning portion of the substrate carrier start to contact each other.

12. The method according to claim 1, further comprising:
driving the substrate carrier to carry the wafer and the cover ring to move toward the blocker from an upper side above the blocker;
decreasing the movement speed of the substrate carrier, when the substrate carrier reaches the second position;
allowing the cover ring to contact the blocker at the contact position;
allowing the cover ring to be placed on the blocker and continuing to drive the substrate carrier to carry the wafer away from the blocker and the cover ring; and
increasing the movement speed of the substrate carrier to move away from the blocker, when the substrate carrier reaches the first position.

13. A method for controlling a substrate carrier of a deposition apparatus, wherein deposition apparatus comprises a chamber, a substrate carrier, a blocker and a cover ring, the substrate carrier, the blocker and the cover ring are disposed within a containing space of the chamber, and the blocker is configured to carry the cover ring; the method comprising:
utilizing the substrate carrier to carry a wafer and the cover ring to move toward the blocker from an upper side above the blocker, and defining a contact position at where the cover ring contacts the blocker start;
defining a first position below the contact position, and defining a second position above the contact position;
decreasing a movement speed of the substrate carrier moving toward the blocker, when the substrate carrier reaches the second position;
allowing the cover ring to contact the blocker at the contact position;
allowing the cover ring to be placed on the blocker and continuing to drive the substrate carrier to move toward the first position; and
increasing the movement speed of the substrate carrier moving away from the blocker, when the substrate carrier reaches the first position.

14. The method according to claim 13, wherein a distance between the first position and the contact position is less than 1 centimeter.

15. The method according to claim 14, wherein the distance between the first position and the contact position is in a range between 2 millimeter and 5 millimeter.

16. The method according to claim 13, wherein a distance between the second position and the contact position is less than 1 centimeter.

17. The method according to claim 16, wherein the distance between the second position and the contact position is in a range between 2 millimeter and 5 millimeter.

18. The method according to claim 13, wherein
disposing a target material disposed on a ceiling of the chamber; and
driving the substrate carrier to carry the wafer and the cover ring to move toward the blocker from the target material.

19. The method according to claim 13, further comprising:
defining a wafer-passing position below the blocker; and
driving the substrate carrier to carry the wafer to move toward the wafer-passing position from the blocker;
wherein the movement speed of the substrate carrier between the wafer-passing position and the first position is faster than the movement speed between the first position and the contact position.

20. The method according to claim 19, further comprising utilizing a robotic arm to pick up the wafer on the substrate carrier move the wafer out of the chamber at the wafer-passing position, when the substrate carrier carries the wafer to the wafer-passing position.
